(19) United States
(12) Patent Application Publication
(10) Pub. No.: US 2020/0243431 A1
(43) Pub. Date: Jul. 30, 2020

(54) STRUCTURE FOR PACKAGING AND METHOD FOR MANUFACTURING THE SAME

(71) Applicant: TYNTEK CORPORATION, Hsinchu City (TW)

(72) Inventors: CHIN-HAN CHOU, MIAOLI COUNTY (TW); WEI-YU CHANG, MIAOLI COUNTY (TW); GUAN-CHEN LIN, MIAOLI COUNTY (TW); I-HSIEN LIN, MIAOLI COUNTY (TW)

(21) Appl. No.: 16/659,756

(22) Filed: Oct. 22, 2019

(30) Foreign Application Priority Data
Jan. 28, 2019 (TW) 108103185

(51) Int. Cl. H01L 23/498; H01L 21/02

(52) U.S. Cl. CPC H01L 23/49822; H01L 23/49894; H01L 21/02282; H01L 21/02488; H01L 21/02403

(57) ABSTRACT

The present invention relates to a structure for packaging and the method for manufacturing the same. The structure for packaging comprise two or more metal members disposed on a substrate or a semiconductor device. A patterned layer and an insulation layer are disposed surrounding the metal members. There is a gap between the patterned layer and the insulation layer. Thereby, while bonding the metal members, metal spilling can be avoided, for further preventing the structure from short circuit or current leakage.

### FIELD OF THE INVENTION

The present invention related to a semiconductor structure and the method for manufacturing the same, and particularly to a structure for packaging and the method for manufacturing the same.

### BACKGROUND OF THE INVENTION

In the semiconductor packaging industry, tin-ball bonding is extensively adopted for forming electrical connection between an integrated-circuit die and a die carrier such as a lead frame or a substrate. In a tin-ball bonding process according to the prior art, the energy selected from the group consisting of heat, pressure and ultrasound is adopted to form a metal connection or soldering between a connecting wire and a connecting pad. As portable electronic products develop prosperously in recent years, various products are developed toward the trend of high density, high performance, light weight, and compact size; various types of package on package are developed as well. Unfortunately, the tin-ball bonding method cannot meet the requirements of light weight, compact size, and high density.

Accordingly, a method for carrying a semiconductor device on a wiring substrate is developed, in which the semiconductor device is connected to the wiring substrate using the flip-chip method. The wiring substrate includes a plurality of semiconductor-device bonding pads on the plane for connecting to the semiconductor device. The plurality of semiconductor-device bonding pads are used for connecting electrically the wiring substrate to the electrode bonding pads of the semiconductor device. In addition, the electrode bonding pads of the semiconductor device are arranged in parallel. Both the semiconductor-device bonding pads on the wiring substrate and the electrode bonding pads of the semiconductor are fabricated by metals with low melting points. Thereby, while bonding, the semiconductor-device bonding pads on the wiring substrate and the electrode bonding pads of the semiconductor are heated and thus softened, close to the liquid phase.

Nonetheless, this connecting method induces another problem. During the pressing and bonding processes, the softened close-to-the-liquid-phase bonding pads may spill some metal blocks or strips, leading to leakage current or short circuit.

To solve the above problems, the present invention provides a structure for packaging and the method for manufacturing the same, which includes a gap between a metal member on the semiconductor device or substrate and an insulation layer acting as the buffer space. Thereby, spilling of metal blocks or strips can be avoided.

### SUMMARY

An objective of the present invention is to provide a structure for packaging and the method for manufacturing the same, which provides a gap between the metal member and the insulation layer and the patterned layer for avoiding spilling of the metal member.

The present invention discloses a structure for packaging, which comprises a semiconductor device, an oxide layer, two or more metal members, and a first insulation layer. The oxide layer is disposed on the semiconductor device and includes two or more accommodation spaces. The two or more metal members are disposed in the two or more accommodation spaces, respectively. The first insulation layer is disposed on the oxide layer.

According to an embodiment of the present invention, a first gap is disposed on one side of one of the two or more metal members.

According to an embodiment of the present invention, a second gap is disposed between the first insulation layer and one of the two or more metal members and not contacting one of the two or more metal members.

According to an embodiment of the present invention, a third gap is disposed below the first gap and between the oxide layer and one of the two or more metal members.

The present invention discloses a structure for packaging, which comprises a substrate, an oxide layer, two or more metal members, and a first insulation layer. The oxide layer is disposed on substrate and includes two or more accommodation spaces. The two or more metal members are disposed in the two or more accommodation spaces, respectively. The first insulation layer is disposed on the oxide layer.

According to an embodiment of the present invention, the substrate includes a p-type semiconductor and an n-type semiconductor.

According to an embodiment of the present invention, a second insulation layer is disposed between one of the two or more metal members and the substrate. A circuit layer is disposed on the second insulation layer.

According to an embodiment of the present invention, a circuit layer is further disposed on the substrate.

According to an embodiment of the present invention, a fourth gap is disposed on one side of the first insulation layer and one of the two or more metal members.

According to an embodiment of the present invention, a fifth gap is disposed between the first insulation layer and one of the two or more metal members and not contacting one of the two or more metal members.

According to an embodiment of the present invention, a sixth gap is disposed below the fourth gap and between the oxide layer and one of the two or more metal members.

According to an embodiment of the present invention, the substrate is a conductive substrate.

The present invention discloses a method for manufacturing a structure for packaging, which comprises steps of providing a semiconductor device; disposing an oxide layer on the semiconductor device; forming a pattern on the semiconductor device, the pattern corresponding to two or more metal members, and the area of the pattern greater than the area of the two or more metal members; removing the oxide layer; disposing an insulation layer on the oxide layer; and disposing the two or more metal member on the semiconductor device.

According to an embodiment of the present invention, spin coating is adopted while coating the oxide layer and the insulation layer on the semiconductor device.

### BRIEF DESCRIPTION OF THE DRAWINGS

FIG. 1A shows a structure diagram of the structure for packaging according to the first embodiment of the present invention;

FIG. 1B shows a top view of the structure for packaging according to the first embodiment of the present invention;

FIG. 2A shows a structure diagram of the structure for packaging according to the second embodiment of the present invention;

FIG. 2B shows a top view of the structure for packaging according to the second embodiment of the present invention;

FIG. 3A shows a structure diagram of the structure for packaging according to the third embodiment of the present invention;

FIG. 3B shows a top view of the structure for packaging according to the third embodiment of the present invention;

FIG. 4A shows a structure diagram of the structure for packaging according to the fourth embodiment of the present invention;

FIG. 4B shows a structure diagram of the structure for packaging according to the fifth embodiment of the present invention;

FIG. 4C shows a structure diagram of the structure for packaging according to the sixth embodiment of the present invention;

FIG. 5A shows a structure diagram of the structure for packaging according to the seventh embodiment of the present invention;

FIG. 5B shows a structure diagram of the structure for packaging according to the eighth embodiment of the present invention;

FIG. 5C shows a structure diagram of the structure for packaging according to the ninth embodiment of the present invention;

FIG. 6A shows a structure diagram of the structure for packaging according to the tenth embodiment of the present invention;

FIG. 6B shows a structure diagram of the structure for packaging according to the eleventh embodiment of the present invention;

FIG. 6C shows a structure diagram of the structure for packaging according to the twelfth embodiment of the present invention;

FIG. 7A shows a structure diagram of the structure for packaging according to the thirteenth embodiment of the present invention;

FIG. 7B shows a structure diagram of the structure for packaging according to the fourteenth embodiment of the present invention;

FIG. 7C shows a structure diagram of the structure for packaging according to the fifteenth embodiment of the present invention;

FIG. 8A shows a step of the method for manufacturing the structure for packaging according to the present invention;

FIG. 8B shows a step of the method for manufacturing the structure for packaging according to the present invention;

FIG. 8C shows a step of the method for manufacturing the structure for packaging according to the present invention;

FIG. 8D shows a step of the method for manufacturing the structure for packaging according to the present invention;

FIG. 8E shows a step of the method for manufacturing the structure for packaging according to the present invention;

FIG. 8F shows a step of the method for manufacturing the structure for packaging according to the present invention;

FIG. 8G shows a step of the method for manufacturing the structure for packaging according to the present invention; and

FIG. 9 shows a flowchart of the method for manufacturing the structure for packaging according to the present invention.

### DETAILED DESCRIPTION

In order to make the structure and characteristics as well as the effectiveness of the present invention to be further understood and recognized, the detailed description of the present invention is provided as follows along with embodiments and accompanying figures.

The present invention provides a structure for packaging and the method for manufacturing the same, in which a gap is provided between the insulation layer the metal member or on the insulation layer for solving the problem of metal spilling while bonding.

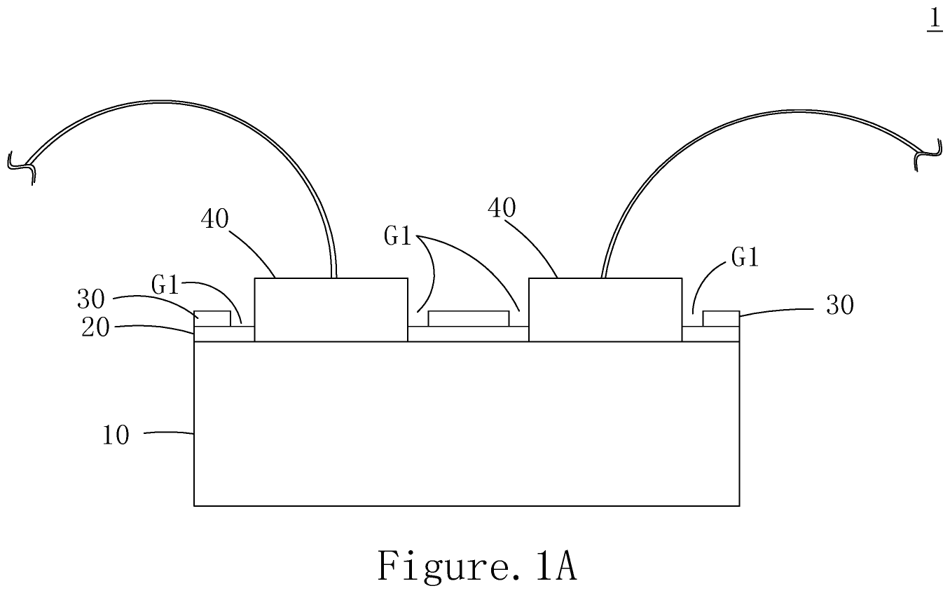

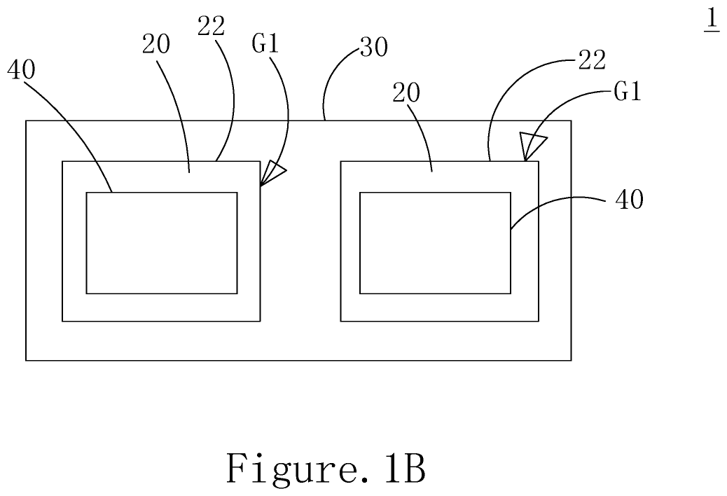

Please refer to FIGS. 1A, 2A, and 3A, which show structure diagrams of the structure for packaging according to the first, second, and third embodiments of the present invention. As shown in FIG. 1A, in the first embodiment, the structure for packaging 1 comprises a semiconductor device 10, an oxide layer 20, an insulation layer 30, and two or more metal members 40. According to the present embodiment, two metal members 40 are adopted for illustration. Nonetheless, according to the present invention, the number of the two or more metal members 40 can be increased according to the circuit design requirements for connecting to external circuitry. The oxide layer 20, the first insulation layer 30, and the two or more metal members 40 are all disposed on the semiconductor device 10. The oxide layer 20 and the first insulation layer 30 surround the two or more metal members and are disposed on the semiconductor device 10. In particular, a first gap G1 is disposed between the first insulation layer 30 and the two or more metal members 40. As shown in FIG. 1B, an accommodation space 22 is disposed on the oxide layer 20 corresponding to the two or more metal members 40, respectively. In addition, the oxide layer 20 attached to the two or more metal members 40. The first insulation layer 30 is disposed on the oxide layer 20. The area of another accommodation space formed by the first insulation layer 30 is greater than the area of the two or more metal members 40. Thereby, the first gap G1 is located between one of the two or more metal members 40 and the first insulation layer 30. Besides, the first gap G1 is an annular gap. Moreover, according to the present invention, the gap G1 can be further disposed between the two or more metal members 40 only for avoiding short circuit caused by spilling of the two or more metal members 40. Thanks to the first gap G1, while assembling the structure for packaging 1, the melt phase of the two or more metal members 40 after heating can flow temporarily into the first gap G1 for avoiding short circuit problem.

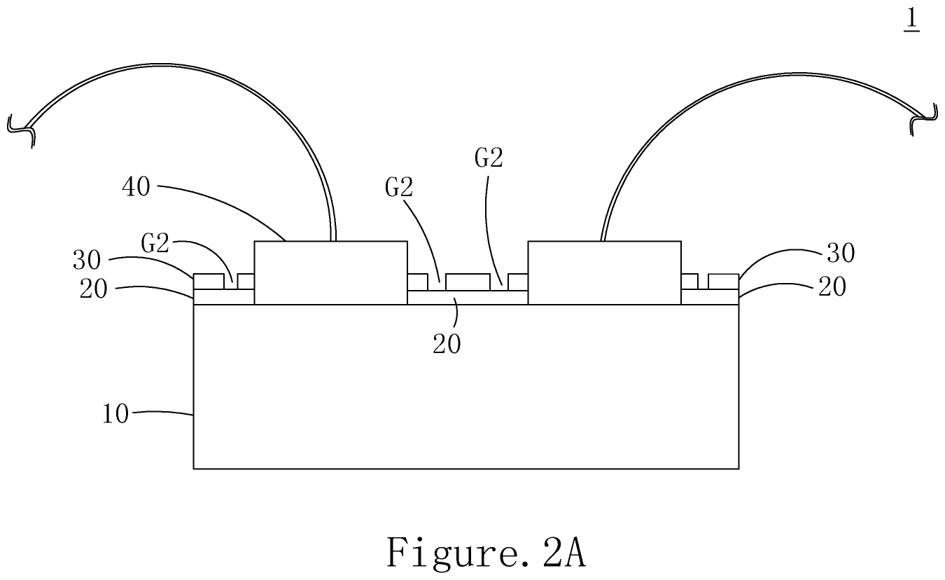

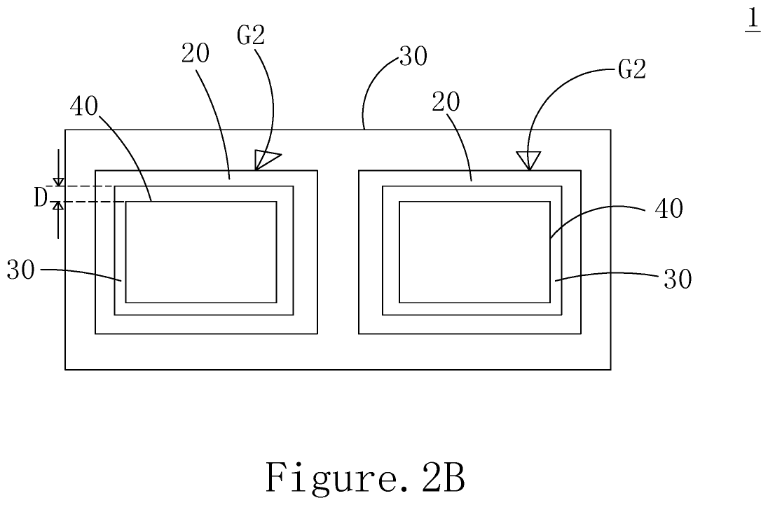

As shown in FIG. 2A, the difference between the second embodiment and the first one shown in FIG. 1A is that in FIG. 1A, the first gap G1 is located between the first insulation layer 30 and one of the two or more metal members 40. In FIG. 2A, the insulation layer 30 is attached to the two or more metal members 40, and a second gap G2 is disposed on the oxide layer 20. As shown in FIG. 2B, the second gap G2 is disposed annularly on the oxide layer 20. There is a spacing distance D between the second gap G2 and the two or more metal members 40. The second gap G2, like an annular trench, is disposed surrounding the two or more metal members 40 with the function identical to that of the first gap G1. Hence, the details will not be described again.

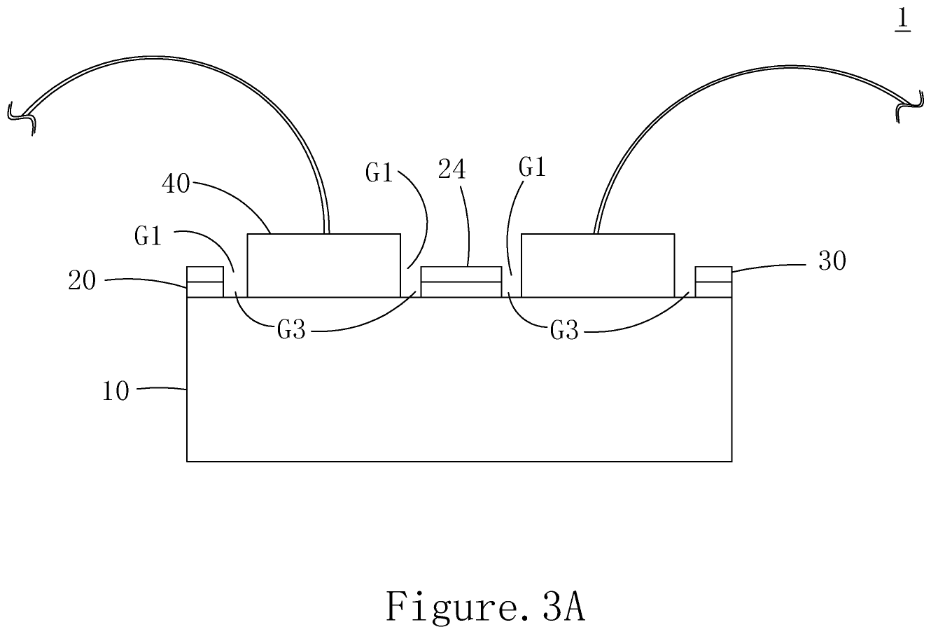

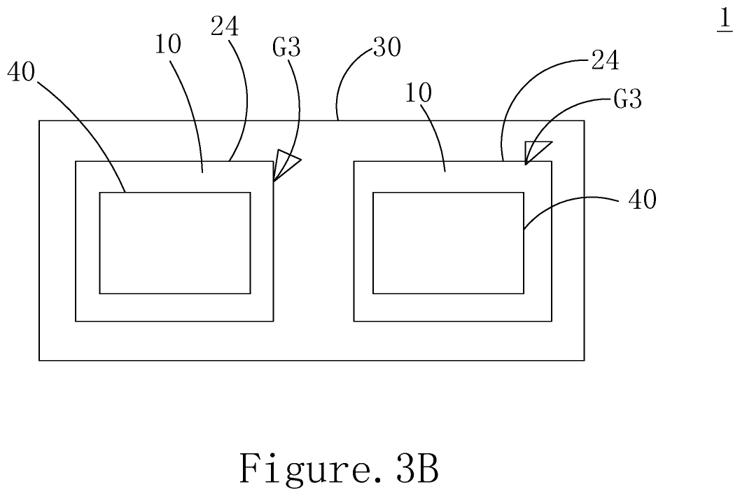

As shown in FIG. 3A, the difference between the third embodiment and the first one shown in FIG. 1A is that in FIG. 1A, the first gap G1 is located on the oxide layer 20. In FIG. 3A, a third gap G3 is disposed below the first gap G1. The third gap G3 is disposed between the oxide layer 20 and one of the two or more metal members 40. The oxide layer 20 and the first insulation layer 30 include gaps corresponding to the two or more metal members 40. Namely, the third gap G3 is equivalent to the first gap G1 extending vertically to the semiconductor device 10. As shown in FIG. 3B, the oxide layer 20 includes an accommodation space 24 with a larger area, forming the third gap G3 surrounding the two or more metal members 40. The surface of the semiconductor device 10 can be seen through the third gap G3. In addition, the function of the third gap G3 is identical to that of the first gap G1. Hence, the details will not be described again.

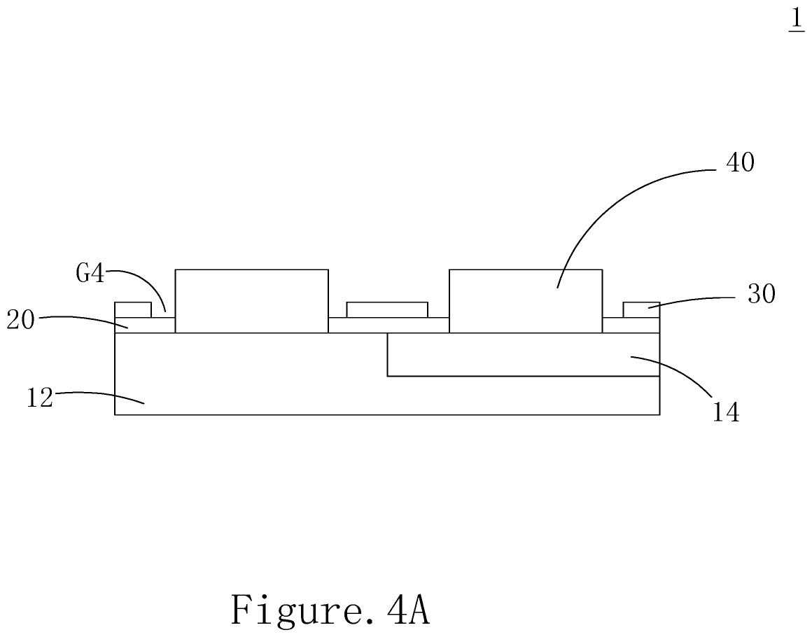

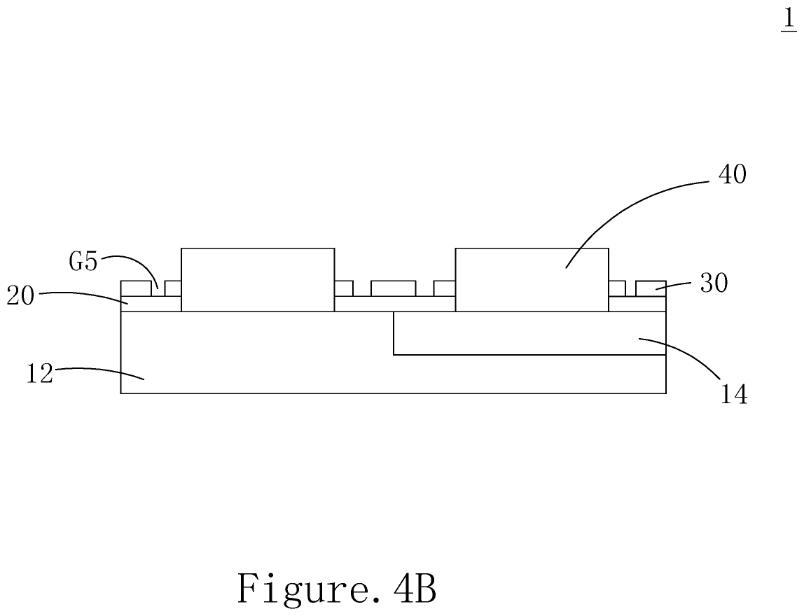

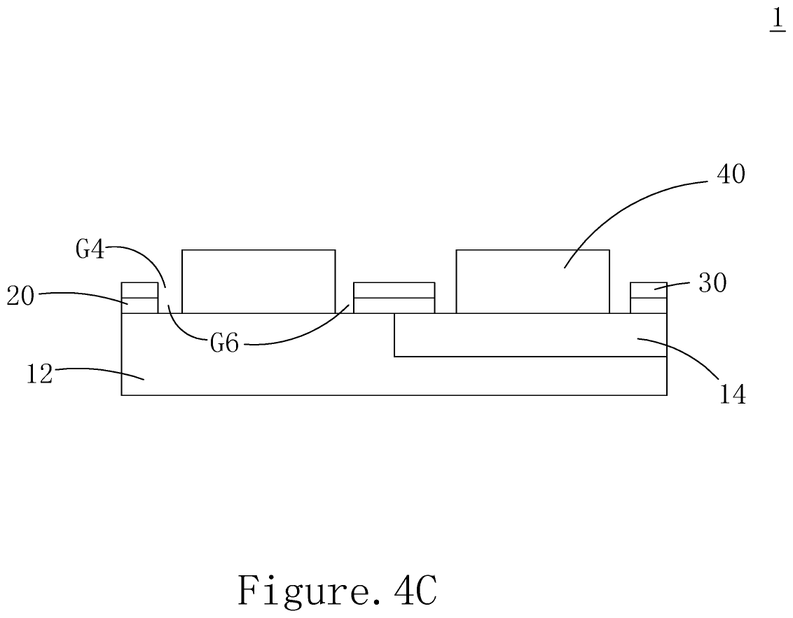

Please refer to FIG. 4A, which shows a structure diagram of the structure for packaging according to the fourth embodiment of the present invention. As shown in the figure, the differences between the fourth embodiment and the first one shown in FIG. 1A are that the semiconductor device 10 according to the fourth embodiment, where is different from the first embodiment, includes an n-type semiconductor 12 and a p-type semiconductor 14, and between the first insulation layer 30 and the two or more metal members 40 are the first gap G1 according to the first embodiment and a fourth gap G4 according to the fourth embodiment. The n-type semiconductor 12 and the p-type semiconductor 14 are disposed below the two or more metal members 40. Besides, the arrangement of the oxide layer 20, the first insulation layer 30, and the fourth gap G4 are identical to those in the first embodiment.

Please refer to FIG. 4B, which shows a structure diagram of the structure for packaging according to the fifth embodiment of the present invention. As shown in the figure, the differences between the fifth embodiment and the second one are that the semiconductor device 10 according to the fifth embodiment includes an n-type semiconductor 12 and a p-type semiconductor 14, and on the oxide layer 20 are the second gap G2 according to the second embodiment and a fifth gap G5 according to the fifth embodiment. The n-type semiconductor 12 and the p-type semiconductor 14 are disposed below the two or more metal members 40. Besides, the arrangement of the oxide layer 20, the first insulation layer 30, and the fifth gap G5 are identical to those in the second embodiment.

Please refer to FIG. 4C, which shows a structure diagram of the structure for packaging according to the sixth embodiment of the present invention. As shown in the figure, the differences between the sixth embodiment and the third one are that the semiconductor device 10 according to the sixth embodiment includes an n-type semiconductor 12 and a p-type semiconductor 14, and below the first gap G1 is the third gap G3 according to the third embodiment and below the fourth gap G4 is a sixth gap G6 according to the sixth embodiment. The n-type semiconductor 12 and the p-type semiconductor 14 are disposed below the two or more metal members 40. Besides, the arrangement of the oxide layer 20, the first insulation layer 30, and the sixth gap G6 are identical to those in the third embodiment.

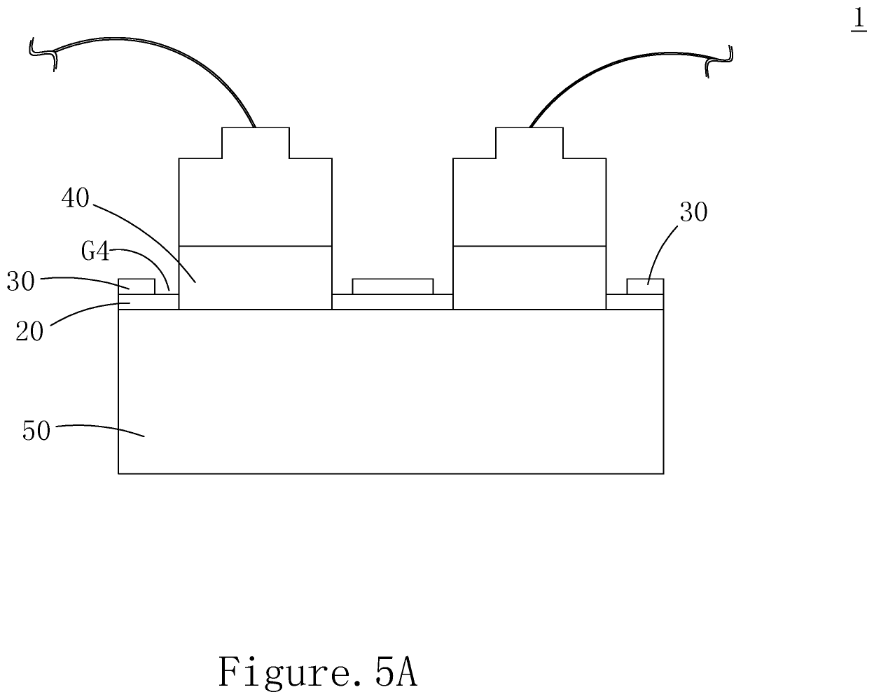

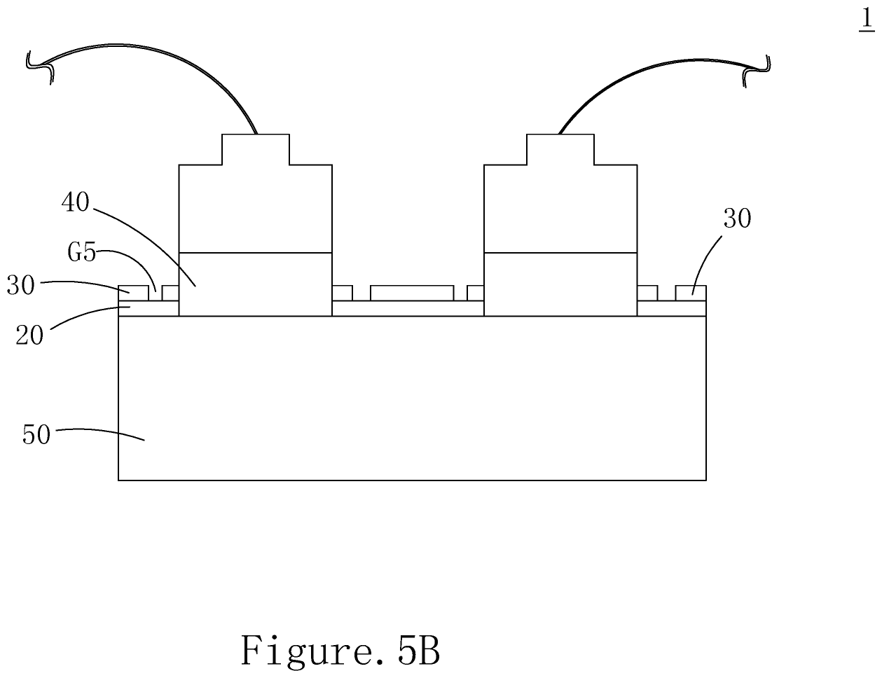

Please refer to FIG. 5A, which shows a structure diagram of the structure for packaging according to the seventh embodiment of the present invention. As shown in the figure, the differences between the seventh embodiment and the first one are that the semiconductor device 10 according to the seventh embodiment is a substrate 50, in particular a conductive substrate, and between the first insulation layer 30 and the two or more metal members 40 are the first gap G1 according to the first embodiment and a fourth gap G4 according to the seventh embodiment. Besides, the arrangement of the oxide layer 20, the first insulation layer 30, and the two or more metal members 40 is identical to that in the first embodiment.

Please refer to FIG. 5B, which shows a structure diagram of the structure for packaging according to the eighth embodiment of the present invention. As shown in the figure, the differences between the eighth embodiment and the second one are that the semiconductor device 10 according to the eighth embodiment is a substrate 50, in particular to a conductive substrate, and on the oxide layer 20 are the second gap G2 according to the second embodiment and a fifth gap G5 according to the eighth embodiment. Besides, the method for disposing the oxide layer 20, the first insulation layer 30, and the two or more metal members 40 is identical to that in the second embodiment.

Please refer to FIG. 5C, which shows a structure diagram of the structure for packaging according to the ninth embodiment of the present invention. As shown in the figure, the differences between the ninth embodiment and the third one are that the semiconductor device 10 according to the ninth embodiment is a substrate 50, in particular a conductive substrate, and below the first gap G1 is the third gap G3 according to the third embodiment and below the fourth gap G4 is a sixth gap G6 according to the ninth embodiment. Besides, the arrangement of the oxide layer 20, the first insulation layer 30, and the two or more metal members 40 is identical to that in the third embodiment.

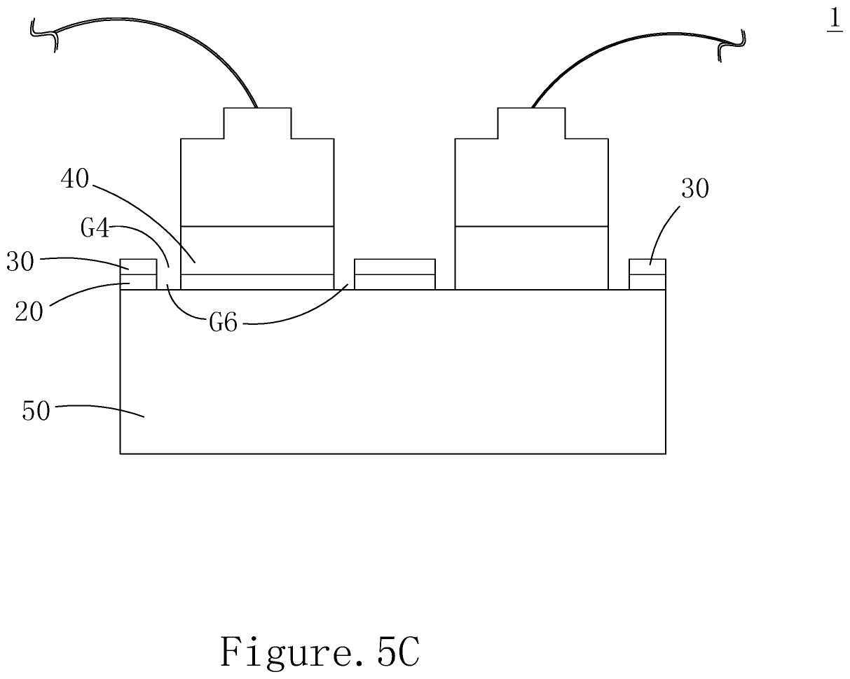

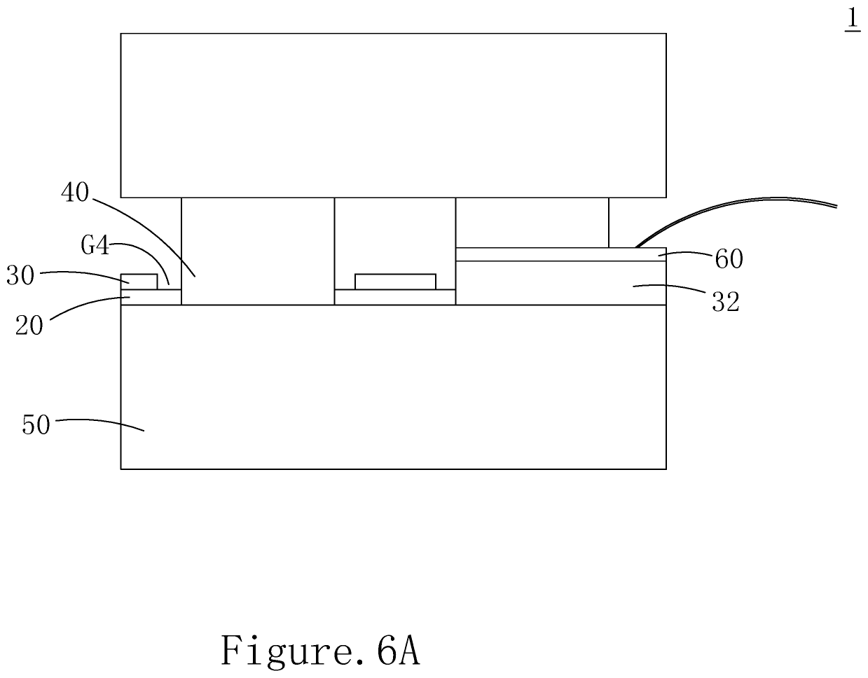

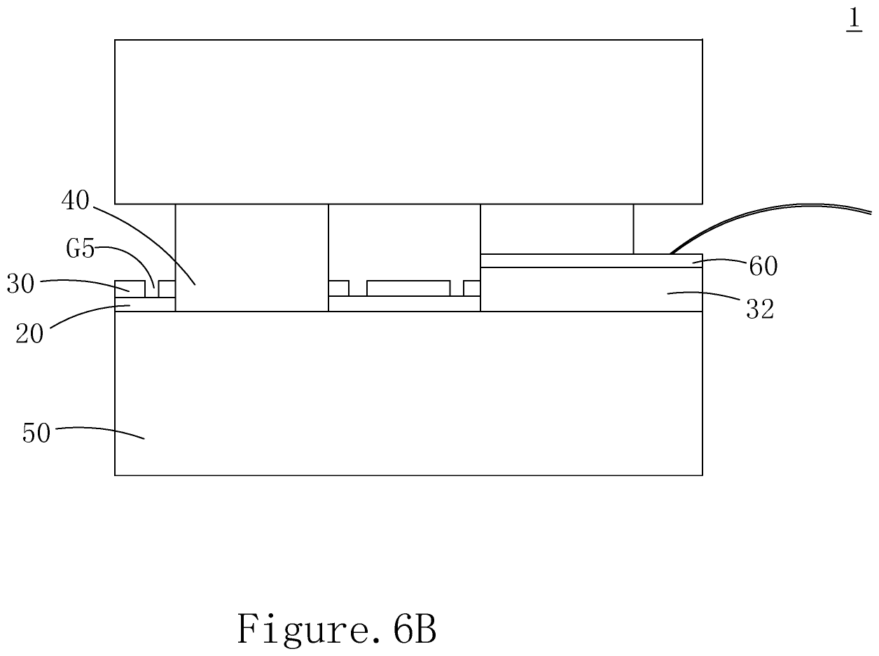

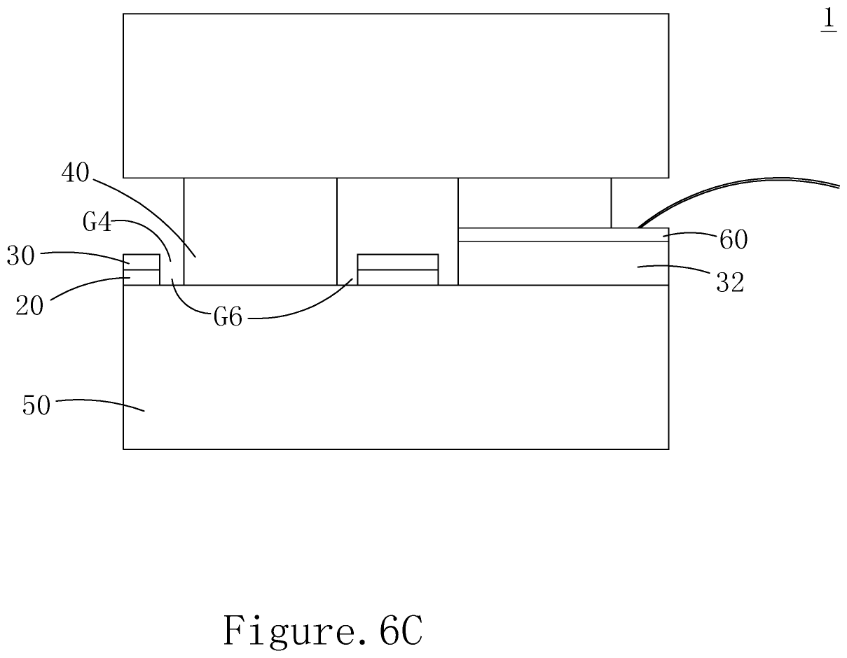

Please refer to FIG. 6A, which shows a structure diagram of the structure for packaging according to the tenth embodiment of the present invention. As shown in the figure, the difference between the tenth embodiment and the first one is that the semiconductor device 10 according to the tenth embodiment is a substrate 50, and in particular a conductive substrate. In addition, a second insulation layer 32 is disposed between one or more of the two or more metal member 40 and the substrate 50. A circuit board 60 is further disposed on the second insulation layer 32. Between the two or more metal members 40 with the second insulation layer 32 and the two or more metal members 40 without the second insulation layer 32, and between the first insulation layer 30 and the two or more metal members 40 are the first gap G1 according to the first embodiment and the fourth gap G4 according to the tenth embodiment. Besides, in this embodiment, the oxide layer 20 and the insulation layer 32 disposed outside the two or more members 40 without the second insulation layer 32 is identical to that of the first embodiment.

Please refer to FIG. 6B, which shows a structure diagram of the structure for packaging according to the eleventh embodiment of the present invention. As shown in the figure, the difference between the eleventh embodiment and the second one is that the semiconductor device 10 according to the eleventh embodiment is a substrate 50, and in particular a conductive substrate. In addition, a second insulation layer 32 is disposed between one or more of the two or more metal member 40 and the substrate 50. A circuit board 60 is further disposed on the second insulation layer 32. Between the two or more metal members 40 with the second insulation layer 32 and the two or more metal members 40 without the second insulation layer 32 are the second gap G2 according to the second embodiment and the fifth gap G5 according to the eleventh embodiment. Besides, the arrangement of the oxide layer 20 and the insulation layer 32 outside the two or more members 40 without the second insulation layer 32 is identical to that of the second embodiment.

Please refer to FIG. 6C, which shows a structure diagram of the structure for packaging according to the twelfth embodiment of the present invention. As shown in the figure, the difference between the twelfth embodiment and the third one is that the semiconductor device 10 according to the twelfth embodiment is a substrate 50, and in particular a conductive substrate. In addition, a second insulation layer 32 is disposed between one or more of the two or more metal member 40 and the substrate 50. A circuit board 60 is further disposed on the second insulation layer 32. The third gap G3 between the two or more metal members 40 with the second insulation layer 32 and the two or more metal members 40 without the second insulation layer 32 is the sixth gap G6. Besides, the arrangement of the oxide layer 20 and the insulation layer 32 outside the two or more members 40 without the second insulation layer 32 is identical to that of the third embodiment.

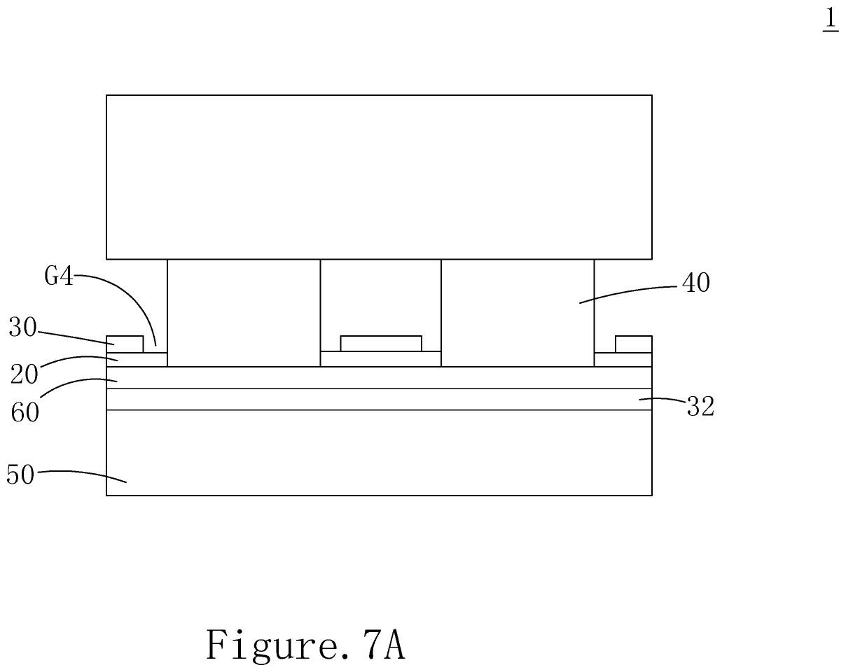

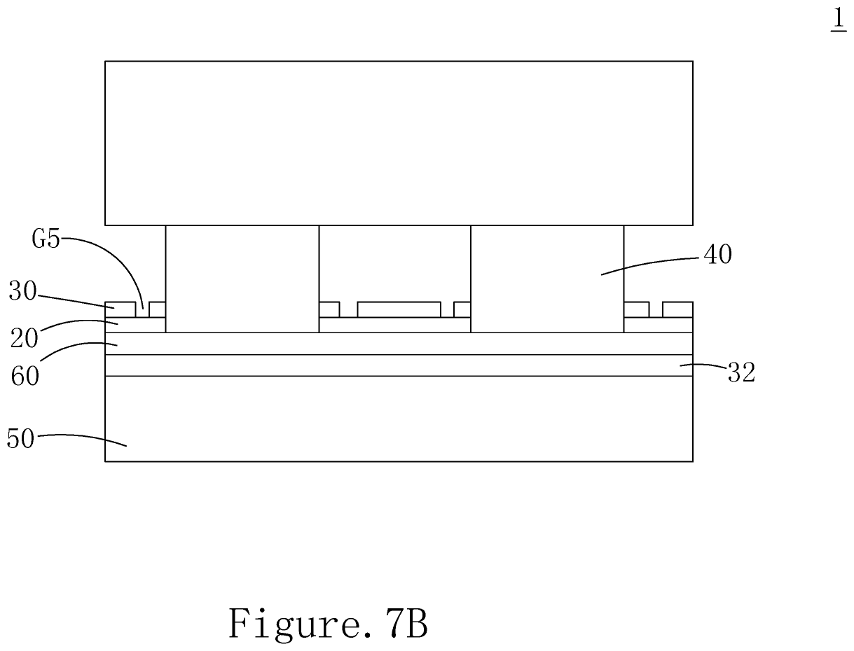

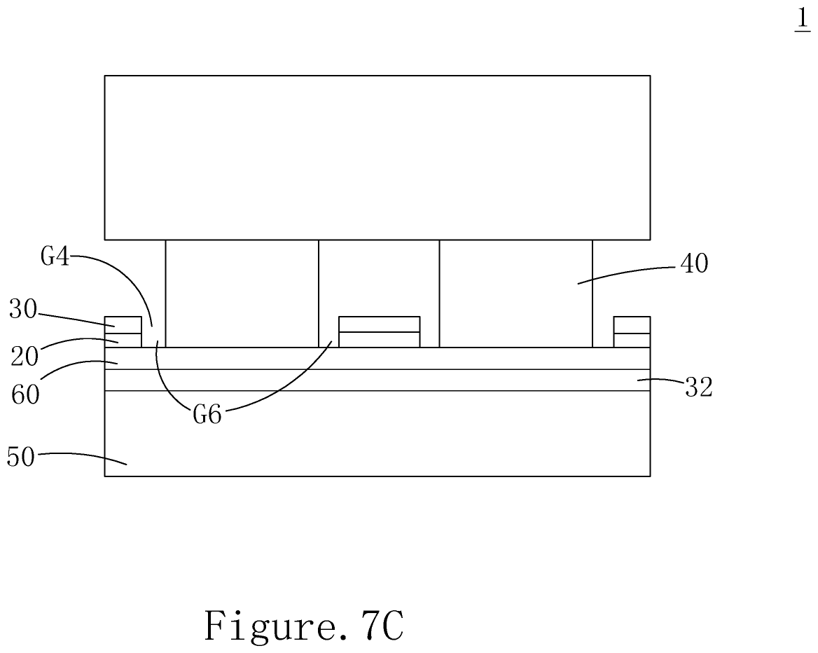

Please refer to FIG. 7A, which shows a structure diagram of the structure for packaging according to the thirteenth embodiment of the present invention. As shown in the figure, the difference between the thirteenth embodiment and the first one is that the semiconductor device 10 according to the thirteenth embodiment is a substrate 50, and in particular a conductive substrate. The second insulation layer 32 is disposed on the substrate 50. The circuit board 60 is disposed on the second insulation layer 32. The oxide layer 20, the first insulation layer 30, and the two or more metal members 40 are all disposed on the circuit board 60. The oxide layer 20 and the first insulation layer 30 surround the two or more metal members 40. The fourth gap G4 is located between the first insulation layer 30 and the two or more metal members 40. An accommodation space 22 (not shown in the figure) is located on the oxide layer 20 corresponding to the two or more metal members 40, respectively. In addition, the oxide layer 20 attaches to the two or more metal members 40. The first insulation layer 30 is disposed on the oxide layer 20. The area of another accommodation space formed by the first insulation layer 30 is greater than area of the two or more metal members 40. Thereby, the fourth gap G4 can be located between the two or more metal members 40 and the first insulation layer 30. The fourth gap G4 is an annular gap. Besides, according to the present invention, the fourth gap G4 can be disposed between the two or more metal members 40 only for avoiding short circuit caused by spilling of the two or more metal members 40. Thanks to the fourth gap G4, while assembling the structure for packaging 1, the melt phase of the two or more metal members 40 after heating can flow temporarily into the fourth gap G4 for avoiding short circuit problem.

Please refer to FIG. 7B, which shows a structure diagram of the structure for packaging according to the fourteenth embodiment of the present invention. As shown in the figure, the difference between the fourteenth embodiment and the second one is that the semiconductor device 10 according to the thirteenth embodiment is a substrate 50, and in particular a conductive substrate. The second gap G2 according to the second embodiment is the fifth gap G5 according to the fourteenth embodiment. The second insulation layer 32 is disposed on the substrate 50. The circuit board 60 is disposed on the second insulation layer 32. The oxide layer 20, the first insulation layer 30, and the two or more metal members 40 are all disposed on the circuit board 60. The function of the fifth gap G5 according to the fourteenth embodiment is identical to that of the second gap G2 according to the second embodiment.

Please refer to FIG. 7C, which shows a structure diagram of the structure for packaging according to the fifteenth embodiment of the present invention. As shown in the figure, the difference between the fifteenth embodiment and the third one is that the semiconductor device 10 according to the fifteenth embodiment is a substrate 50, and in particular a conductive substrate. The third gap G3 according to the third embodiment is the sixth gap G6 according to the fifteenth embodiment. The first gap G1 is the fourth gap G4. The second insulation layer 32 is disposed on the substrate 50. The circuit board 60 is disposed on the second insulation layer 32. The oxide layer 20, the first insulation layer 30, and the two or more metal members 40 are all disposed on the circuit board 60. The function of the sixth gap G6 and the fourth gap G4 according to the fifteenth embodiment is identical to that of the third gap G3 and the first gap G1 according to the third embodiment.

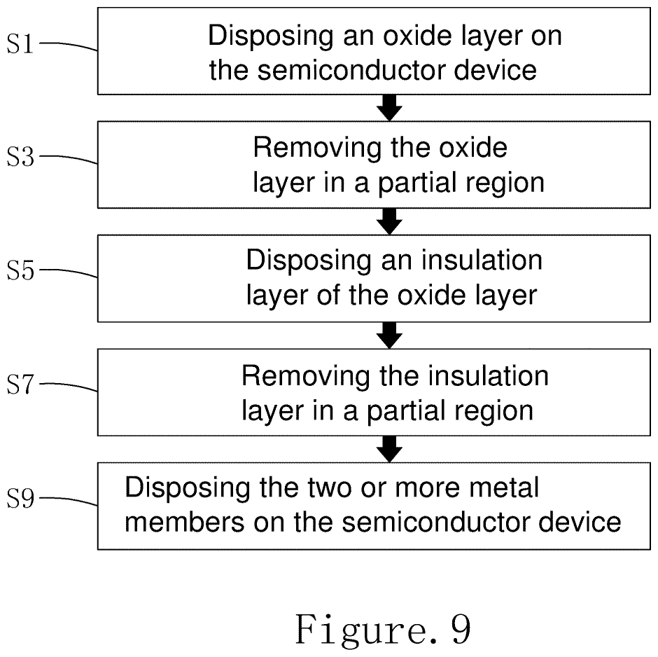

Please refer to FIG. 9, which shows a flowchart of the method for manufacturing the structure for packaging according to the present invention. As shown in the figure, the method comprises steps of:

Step S1: Disposing an oxide layer on the semiconductor device;
Step S3: Removing the oxide layer in a partial region;
Step S5: Disposing an insulation layer of the oxide layer;
Step S7: Removing the insulation layer in a partial region;
Step S9: Disposing the two or more metal members on the semiconductor device.

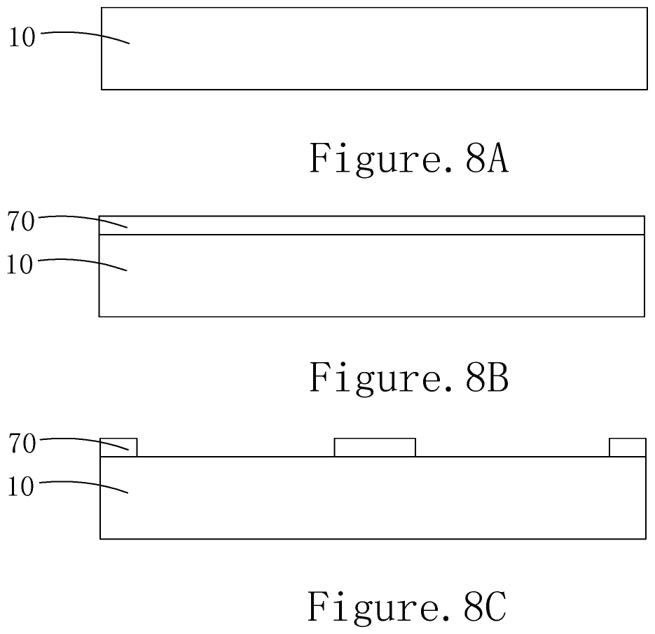

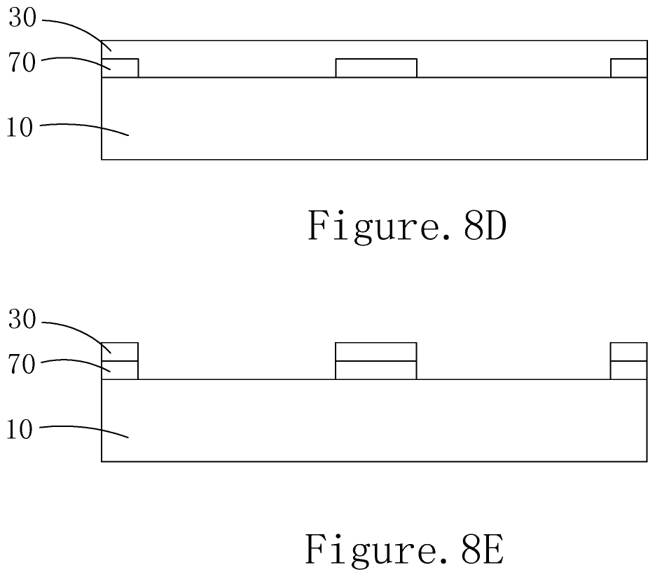

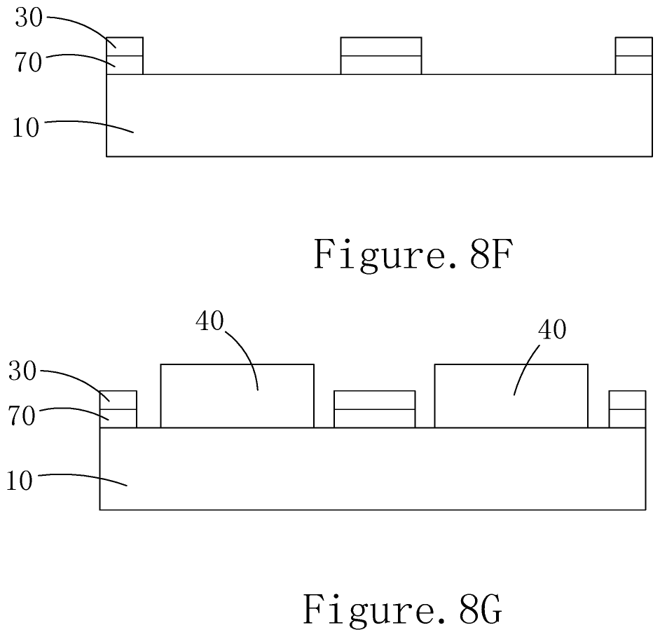

In the step S1, please refer to FIGS. 8A to 8C, which show steps of the method for manufacturing the structure for packaging according to the present invention. As shown in the figures, first, a semiconductor device 10 is provided. An oxide layer 70 is spin coated on the semiconductor device 10.

In the step S3, the oxide layer is baked. In addition, photography and exposure processes are performed on the oxide layer, and hence forming the residual oxide layer 70, which is a pattern corresponding to the two or more metal members. The area of the pattern is greater than the area of the two or more metal members.

In the step S5, please refer to FIGS. 8D and 8E, which show steps of the method for manufacturing the structure for packaging according to the present invention. As shown in the figures, an insulation layer 30 is coated on the residual oxide layer 70.

In the step S7, the oxide layer is baked. In addition, photography and exposure processes are performed on the insulation layer 30, and hence forming the residual insulation layer 30.

In the step S9, please refer to FIGS. 8F and 8G, which show steps of the method for manufacturing the structure for packaging according to the present invention. As shown in the figures, the two metal members 40 are disposed in the regions for removing the oxide layer 70 and the insulation layer 30, respectively. Various gaps are formed between the oxide layer 70, the insulation layer 30, and the two or more metal members 40 for meeting different requirements.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

What is claimed is:

1. A structure for packaging, comprising:
a semiconductor device;
an oxide layer, disposed on said semiconductor device, including two or more accommodation spaces;
two or more metal members, disposed in said two or more accommodation spaces; and
a first insulation layer, disposed on said oxide layer.

2. The structure for packaging of claim 1, wherein a first gap is disposed on one side of one said two or more metal members; a second gap is further disposed between said first insulation layer and one of said two or more metal members and not contacting one of said two or more metal members; a third gap is disposed below said first gap and between said oxide layer and one of said two or more metal members.

3. A structure for packaging, comprising:
a substrate;
an oxide layer, disposed on said substrate, including two or more accommodation spaces;
two or more metal members, disposed in said two or more accommodation spaces; and
a first insulation layer, disposed on said oxide layer.

4. The structure for packaging of claim 3, wherein a fourth gap is disposed between said first insulation layer and one side of one of said two or more metal members.

5. The structure for packaging of claim 3, further comprising a fifth gap, disposed between said first insulation layer and one of said two or more metal members, and not contacting one of said two or more metal members.

6. The structure for packaging of claim 3, wherein said substrate is a conductive substrate.

7. The structure for packaging of claim 3, wherein said substrate includes a p-type semiconductor and an n-type semiconductor.

8. The structure for packaging of claim 7, wherein a fourth gap is disposed between said first insulation layer and one side of one of said two or more metal members.

9. The structure for packaging of claim 7, wherein a fifth gap is disposed between said first insulation layer and one of said two or more metal members, and not contacting one of said two or more metal members.

10. The structure for packaging of claim 3, wherein a second insulation layer is disposed between one of said two or more metal members and said substrate, and a circuit layer is disposed on said second insulation layer.

11. The structure for packaging of claim 10, wherein a fourth gap is disposed between said first insulation layer and one side of one of said two or more metal members.

12. The structure for packaging of claim 10, wherein a fifth gap is disposed between said first insulation layer and one of said two or more metal members, and not contacting one of said two or more metal members.

13. The structure for packaging of claim 10, wherein said substrate is a conductive substrate.

14. The structure for packaging of claim 3, wherein a second insulation layer is further disposed between on said substrate, and a circuit layer is disposed on said second insulation layer.

15. The structure for packaging of claim 14, wherein a fourth gap is disposed between said first insulation layer and one side of one of said two or more metal members.

16. The structure for packaging of claim 14, wherein a fifth gap is disposed between said first insulation layer and one of said two or more metal members, and not contacting one of said two or more metal members.

17. The structure for packaging of claim 15, wherein a sixth gap is disposed below said fourth gap and between said oxide layer and one of said two or more metal members.

18. The structure for packaging of claim 14, wherein said substrate is a conductive substrate.

19. A method for manufacturing a structure for packaging, comprising steps of:
providing a semiconductor device;
disposing an oxide layer on said semiconductor device;
forming a pattern on said semiconductor device, said pattern corresponding to two or more metal members, and the area of said pattern greater than the area of said two or more metal members;
removing said oxide layer;
disposing an insulation layer on said oxide layer; and
disposing said two or more metal member on said semiconductor device.

20. The method for manufacturing a structure for packaging of claim 19, wherein spin coating is adopted for coating said oxide layer and said insulation layer on said semiconductor device.
